(19) United States
(12) Patent Application Publication
(10) Pub. No.: US 2015/0084778 A1
(43) Pub. Date: Mar. 26, 2015

(54) SYSTEM AND METHOD TO ESTIMATE DURATION OF BATTERY (DIS)CHARGING OF AN ELECTRONIC DEVICE AND PROVIDE SMART CHARGING ALERTS BASED ON DEVICE USAGE PATTERN

(71) Applicant: MOTOROLA MOBILITY LLC, Libertyville, IL (US)

(72) Inventors: Rachit Mittal, Bangalore (IN); Amit Kumar Agrawal, Bangalore (IN)

(73) Assignee: MOTOROLA MOBILITY LLC, Libertyville, IL (US)

(21) Appl. No.: 14/038,035

(22) Filed: Sep. 26, 2013

(51) Int. Cl. G01R 19/165

(52) U.S. Cl. CPC G01R 19/16542
USPC 340/636.16

(57) ABSTRACT

A portable electronic (PE) device and method generates contextual power alerts related to a power source of the PE device. The method includes identifying a future interval of usage of the PE device based on a usage pattern associated with at least one of a user profile and usage of the PE device. The method further includes estimating, based on the usage pattern, an amount of charge that is necessary for the power source to power the use of the PE device through the future interval. In response to determining that the amount of charge required for use of the PE device through the future interval is greater than an amount of stored charge currently available, the method further includes producing a user alert indicating that the PE device will require charging in order to provide the amount of charge required to power the PE device through the future interval.

### BACKGROUND

1. Technical Field

The present disclosure generally relates to portable electronic devices and in particular to portable electronic (PE) devices that operate on a depletable power source, such as a battery.

2. Description of the Related Art

Portable electronic (PE) devices typically display remaining battery power as a percentage of total capacity. Thereby, users of PE devices are given an indication of a state of charge of the battery. However, the rate of discharge of many PE devices can vary widely depending upon what applications are running and/or what services are being performed by the respective device. As such, the user is not given insight into how long his portable electronic device can continue operating before the battery is completely discharged.

### BRIEF DESCRIPTION OF THE DRAWINGS

The disclosure will best be understood by reference to the following detailed description of illustrative embodiments when read in conjunction with the accompanying drawings, wherein:

FIG. 1 illustrates a block diagram of a personal electronic (PE) device that is portably powered by a power source and which generates contextual power alerts for the PE device, according to one or more embodiments;

FIG. 2 illustrates a detailed block diagram of the component makeup of one example PE device, such as provided by FIG. 1, which is configured to operate as a smart wireless communication device, according to at least one embodiment;

FIG. 3 illustrates a flow chart of an example method for generating contextual power alerts related to a power source of a PE device, according to at least one embodiment;

FIG. 4 illustrates a flow chart of an example method for detecting rates of discharging and for updating usage pattern based upon context, according to at least one embodiment;

FIG. 5 illustrates a flow chart of an additional example method for detecting rates of charging and for notifying a user as to an amount of time required to charge the PE device for a future interval, according to at least one embodiment;

FIG. 6 illustrates a flow chart of a further example method for determining that charging is available based upon a current context and previously evaluated charging events, according to at least one embodiment;

FIG. 7 illustrates a flow chart of yet another example method for categorizing a current context and for updating a historical usage pattern of the PE device, according to at least one embodiment;

FIG. 8 illustrates a flow chart of yet a further example method for sharing a usage pattern data by uploading a user profile between PE devices associated with a same user, according to at least one embodiment; and

FIG. 9 illustrates a flow chart of yet another example method for sharing the usage pattern data by downloading a user profile between PE devices associated with the same user, according to at least one embodiment.

### DETAILED DESCRIPTION

The illustrative embodiments of the present disclosure provide a portable electronic (PE) device and method that generates contextual power alerts related to a power source of the PE device. According to one aspect, a method includes identifying a future interval of usage of the PE device based on a usage pattern associated with at least one of a user profile and usage of the PE device. The method further includes estimating, based on the usage pattern, an amount of charge that is needed for the power source to power the use of the PE device through the future interval. In response to determining that the amount of charge required to power the PE device through the future interval is greater than an amount of charge currently available from the power source, the method further includes producing a user alert indicating that the PE device will require charging in order to provide the amount of charge required to power the PE device through the future interval.

According to another aspect, a PE device has a power source, at least one processor that is powered by the power source, one or more applications selectively executed by the at least one processor, and a user interface device that is communicatively coupled to the at least one processor. A power utility executes on the at least one processor and configures the PE device to identify a future interval of usage of the PE device based on a usage pattern associated with at least one of a user profile and usage of the PE device. The power utility further configures the PE device to estimate, based on the usage pattern, an amount of charge that is necessary for the power source to power the use of the PE device through the future interval. In response to determining that the amount of charge required for use of the PE device through the future interval is greater than an amount of charge currently available from the power source, the power utility further configures the PE device to produce a user alert indicating that the PE device will require charging in order to provide the amount of charge required to power the PE device through the future interval.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present disclosure. The following detailed description is, therefore, not to be taken in a limiting sense, and the scope of the present disclosure is defined by the appended claims and equivalents thereof.

Within the descriptions of the different views of the figures, similar elements are provided similar names and reference numerals as those of the previous figure(s). The specific numerals assigned to the elements are provided solely to aid in the description and are not meant to imply any limitations (structural or functional or otherwise) on the described embodiment. It will be appreciated that for simplicity and clarity of illustration, elements illustrated in the figures have not necessarily been drawn to scale. For example, the dimensions of some of the elements are exaggerated relative to other elements.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention.

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein.

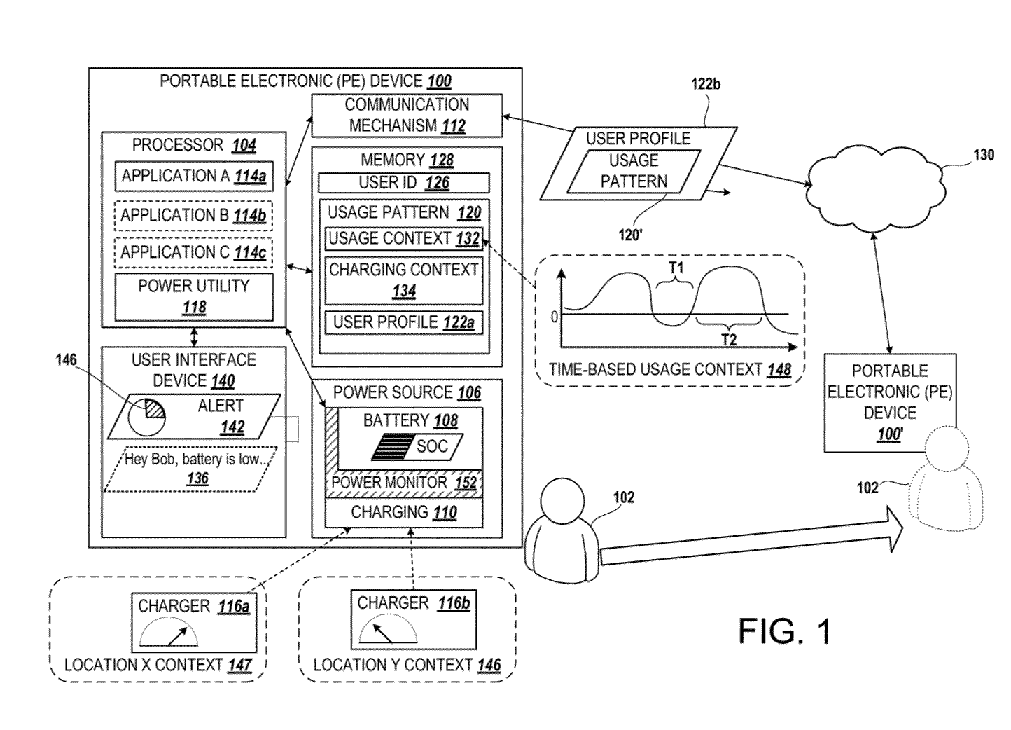

Turning now to FIG. 1, there is depicted a block diagram representation of an example portable electronic (PE) device 100 within which several of the features of the disclosure can be implemented. According to the general illustration, the PE device 100 is a processing device of a user 102 having at least one processor 104 and which is powered by a power source 106. Power source 106 can include a component that stores charge, such as battery 108. In embodiments in which the power storing component is rechargeable, power source 106 can also include charging subcircuit or component 110. One or more applications 114a-c can be selectively executed by the at least one processor 104. Battery 108 can provide power required to support execution of one or more of these applications for a finite time, which time varies according to such usage and a state of charge (SOC) of the battery 108. The battery 108 can be replaceable, rechargeable or both.

For clarity, the one or more applications are depicted as application A 114a, application B 114b, and application C 114c, whose selective execution cause differing power demands on the power source 106. It should be appreciated that an embodiment can include an application that changes its mode of operation, such as duty cycle, activation of communication mechanism 112, and frequency of memory access reads/writes, etc., that can in effect act as selective execution of one or more applications.

In addition to variations due to rate of discharge, the length of time over which the power source 106 can support the usage of the PE device 100 can also depend at least in part upon availability and rate of charging of the battery 108 by an external charger. For example, a charging component 110 of the power source 106 can receive charging from an external charger 116a that provides a fast rate of recharging, such a wall outlet transformer or car charger. Alternatively, the charging component 110 can receive charging from an external charger 116b that provides a slow rate of recharging, such as a universal serial bus (USB) cable connected to a personal computer workstation or laptop.

A power utility 118 can execute on the at least one processor 104 to configure the PE device 100 to perform functions of providing a real time estimate of battery charge and discharge duration based on an available usage pattern. In particular, the power utility 118 can intelligently recommend that a user charge the PE device 100 based on context information. In one embodiment, the power utility 118 configures the PE device 100 to identify a future interval of usage of the PE device 100 based on a usage pattern 120 associated with at least one of (i) a user profile 122b, which may be downloaded onto the PE device from another device or server, and (ii) a user profile 122a that is locally generated based on detected usage of the PE device 100, and (iii) a combination of user profile data received from another device and user profile data that is locally detected and recorded. For purposes of the disclosure, all future references shall be to user profile 122 generally, regardless of the specific origin of the user profile data. The power utility 118 can then estimate, based on the usage pattern 120, an amount of charge that is necessary for the power source 106 for use of the PE device 100 during the period lasting until the end of the future interval or until a next available charging opportunity. In response to determining that the amount of charge required for use of the PE device 100 through the future interval is greater than an amount of charge currently available from the power source 106, the power utility 118 produces a user alert 142 via user interface device 140 indicating that the battery 108 of the PE device 100 will require charging in order to provide the amount of charge required to power the device through the future interval. The user interface device 140 can be directly communicatively coupled to the at least one processor 104.

As used herein, a future interval of usage of the PE device 100 can refer to defined period of time in the future. A starting point and ending point can be of a fixed relationship. For example, a future interval can look to power requirements for a period of time starting one hour from now and ending two hours from now. Alternatively, the future interval can be defined as a predicted future period during which charging is not expected to be available based upon the charging aspects of the usage pattern 120. For example, there can be defined a period of time associated with a morning commute, an afternoon commute, and an exercise period, during which charging is not available for the device. Each period of time can have an average duration that differs from the others. Also, the amount of time until the start of the future interval can be fixed or can be variable. For example, an expected requirement for a long interval at high usage can require a greater advanced warning in order to have sufficient time for charging. Alternatively, the power source 106 can already be at a high state of charge or an available charger can provide a quick recharging and thus the future interval start time can be relatively close to the current time.

The power utility 118 of the PE device 100 can detect and record a discharging rate from the power source 106 over periods of active and inactive use of the PE device 100. In response to detecting a change in the usage pattern 120, the power utility 118 can update the usage pattern 120 to account for the change. The power utility 118 can associate the usage pattern 120 with the user profile 122 corresponding to an owner based upon a user Identification (ID) 126 stored in memory 128 of the PE device 100.

In one embodiment, the power source 106 holds an amount of charge, depicted as a state of charge (SOC) of battery 108 that ranges from a full charge to no charge. The amount of charge is depleted at varying rates based on a level of device usage. The power utility 118 can configure the PE device 100 to detect discharging rates of the power source 106 over at least one discharging interval by receiving signals from a power monitor 152 that monitors current or charge drawn from the battery 108. The power monitor 152 can also detect power or charge added to the battery 108 by a charger 116a, 116b. According to one aspect, this discharging interval can be identified as one that is re-occurring with some periodicity, such that a future interval would predictably have similar power usage as the monitored at least one discharging interval. The power utility 118 determines a minimum amount of charge required for the power source 106 to power the usage of the PE device 100 during the at least one discharging interval without a loss of power. The power utility 118 tracks and maintains a usage context 132 that provides a record of the discharging rates and the amount of charge required correlated to one or more identifying characteristics of the at least one discharging interval. The power utility 118 identifies a notification period prior to the at least one discharging interval that is sufficient to (a) alert a user 102 of the PE device 100 of a potential loss of power through the future interval based on a remaining charge for the power source 106 being below the minimum amount of charge required and (b) allow the user 102 to take corrective action before the future interval. The power utility 118 also triggers the presentation of the user alert 142 in response to determining a start point of the notification period preceding the future interval.

In one embodiment, the power source 106 is a rechargeable power source and the corrective action involves recharging the power source 106 above the minimum amount of charge. The notification period is selected to provide sufficient time before the future interval during which the power source 106 can be charged to above the minimum amount of charge, based on the available charging rate. The power utility 118 further configures the PE device 100 to detect charging rates of the power source 106 over at least one charging interval that occurs within the notification period, prior to the at least one discharging interval. The PE device 100 generates and maintains a charging context 134 that provides a record of at least one of (i) times and (ii) locations at which the power source 106 is charged, including during the notification period, along with associated charging rates for each time and/or location. The PE device 100 further evaluates, based on at least a charging context 134 correlated to the notification period, an amount of time required to charge the power source 106 to a power level above the minimum amount of charge required to allow usage of the PE device 100 during an entirety of the future interval. The user alert 142 includes a notification 136 of the amount of time that the power source 106 of the PE device 100 should be charged in order to meet the minimum amount of charge required for operation through the future interval.

For a charge use case, when the user 102 attaches the PE device 100 or places it within induction proximity to the external charger 116a, the PE device 100 displays estimated time required to charge the battery 108. For example, based upon a determination that the SOC of the battery 108 is 40%, the PE device 100 can display “Device requires 2 hours to charge completely”. Optionally, the PE device 100 can also give details on how much time it may take to charge 50%, 60% SOC, etc., as compared to completely charged state (100% SOC).

The user alert 142 provided by the PE device 100 can be a “smart” alert. For example, the user 102 listens to music on his PE device 100 every evening while traveling from his office in Location Y to his home in Location X. The power utility 118 can associate a first charging rate provided by charger 116a with a location-based usage context 146 for location X. The power utility 118 can associate a second charging rate provided by charger 116b with a location-based usage context 147 for location Y. The power utility 118 of the PE device 100 determines that the PE device 100 needs at least 40% SOC in order to play music this evening for the travel duration to Bob's home, but that the battery 108 is only 20% charged. Based on knowledge of the charge rate available for charging the PE device 100 at Bob's office, at 2:30 p.m., PE device 100 provides a user alert 142 to Bob with a notification 136 as follows:
“Hey Bob, battery is low; please plug-in for at least 20 minutes to enjoy music on your way back home.”

In one implementation, the analysis of the charge rate also takes into account the availability to Bob of an in-vehicle charger capable of providing a slower charge rate that is not sufficient to keep the PE device 100 charged for the duration of the drive home, unless some charging occurs at the office. In such a use case, the PE device 100 can factor in the available slower charging option and provide a user alert with a more detailed notification, such as:
“Hey Bob, battery is low. To enjoy music on your way back home, please plug in to outlet for 15 minutes now if you have your car charger or for 20 minutes if you do not have your car charger.”

In one embodiment, a current drain usage pattern learning algorithm can be described using the following list of variables:

| | |
|---|---|
| x | Bigger intervals (e.g., 60 minutes) |
| y | Smaller intervals (e.g., 5 minutes) |
| CD(x) | Current drain in duration x |
| CA(y) | Charging availability - probability of device connected |
| | to a charger during this specific duration |
| CD(y) | Current drain in duration y |
| t1 | Most recent average of x for a particular duration |
| | (e.g., 3-4 p.m. under either working/non-working category) |
| t2 | Most recent average of y for a particular duration |
| t3 | Average battery drain for the whole day |
| n | Day of the learning |

The value t1 and t2 can be calculated as follows:

t2={[(t1*y*n)/x]+CD(y)}/(n+1) Eqn. 1

with a subsequent a can be determined as follows:

t1=Σ(t₂m), where m is an integer in 1≦m≦x/y Eqn. 2

(e.g., t2₁+t2₂+ . . . t2₁₂)

The power utility 118 of the PE device 100 can detect high usage applications. The value t3 is the most recent average of battery usage for the whole day under specific day category

CD(X)≧(t3*threshold percentage)+t3 Eqn. 3

where “threshold percentage” is configurable and could be device and implementation specific (e.g. variance of more than 50%, computed as a ratio of the smaller value to the larger value of the recorded average to the most recent average). A determination that the above expression is true can be a clear indication of high usage. A PE device 100 can make a record of running (battery consuming) applications along with the specific duration under specific time-based usage context 148.

Estimation of duration to charge the device: Once the PE device 100 is connected to the charger, the power utility 118 senses the charging rate. The power utility 118 can access the amount of discharged battery and estimated battery usage based on a learning algorithm. Considering the above information, power utility 118 provides the estimated charging duration for 100% charged. This data can be further presented in more granular level to display charging time duration to complete 50%, 60% . . . 90% charge.

The power utility 118 can make a recommendation to the user 102 in response to predicting high usage during a future interval, such as by associating a time-based usage context. Consider a use case (a) for indications before the next charging period availability:

Current Battery Charge (CBC)=500 mAh

Expected Charge requirement (ECR) until next charging availability=700 mAh

Input Current (IC)=400 mA

TABLE A

| | | | | | |
|---|---|---|---|---|---|
| Estimated | 100 | 100 | 150 | 350 | 100 |
| Usage | mAh | mAh | mAh | mAh | mAh |
| Duration on | 2-3 | 3-4 | 4-5 | 5-6 | 6-7 |
| a specific | pm | pm | pm | pm | pm |
| day | | | | | |
| Usage Patterns | | | High | Charging | |
| Flags | | | Usage | availability | |
| | | | Pattern | duration | |
| Expected | 400 | 300 | 150 | Battery | |
| Remaining | mAh | mAh | mAh | will die | |
| Battery charge | | | | in between | |
| at the end | | | | | |
| of duration | | | | | |

Estimated Duration for which charging needed=(ECR−CBC)/IC (e.g., charging needed=(700−500)/400=0.5 hours=30 minutes). Using above calculations, the power utility 118 can provide to the user 102 an alert:
“Device needs to be charged for at least 30 minutes to enjoy <Particular App> in the <Evening/Night>”

The power utility 118 can also provide an alert for a use case (b) wherein the location-based usage context indicates that charging is available during a present time interval “T1” but will be insufficient for a future time interval “T2” of a time-based usage context 148:

Current Battery Charge (CBC)=300 mAh

Expected Current requirement (ECR) for near future high usage=700 mAh

Expected Battery gain in between (EBG)=300 mAh

Input Current (IC)=400 mA

TABLE B

| | | | | | |
|---|---|---|---|---|---|
| Estimated | 100 | 100 | 150 | 350 | 100 |
| Usage | mAh | mAh | mAh | mAh | mAh |
| Duration on | 2-3 | 3-4 | 4-5 | 5-6 | 6-7 |
| a specific | pm | pm | pm | pm | pm |
| day | | | | | |
| Usage Patterns | | Charging | | High | Charging |
| Flags | | availability | | Usage | availability |
| | | duration | | Pattern | duration |
| Expected | 200 | 400 mAh | 150 | Battery | |
| Remaining | mAh | (300 mAh | mAh | will die | |
| Battery charge | | is added | | in between | |
| at the end | | due to | | | |
| of duration | | charging) | | | |

Estimated duration for which additional charging needed=(ECR−EBG−CBC)/IC (e.g., additional charging needed=(700−600)/400=0.25 hours=15 minutes). Using above calculations user can be recommended/alerted in the following fashion:
“Device needs to be charged for additional 15 minutes to enjoy <Particular App> in the <Evening/Night>”

According to at least one embodiment, the PE device 100 and another PE device 100′ can be used by the same user 102. The user profile 122 can be based upon usage or either or both of the PE devices 100, 100′ by the user 102. The PE device 100 and a second PE device 100′ can represent a replacement with an identical or similar device. Alternatively, the PE device 100 and the second PE device 100′ can represent dissimilar devices that are used for similar functions (e.g., messaging, communication, navigation, entertainment, etc.). For example, the second PE device 100′ can have dissimilar power usage for a particular type of application yet benefit from knowing the usage pattern 120 for availability of charging, types of functions used during particular times of day or day of the week, etc. The second PE device 100′ can update the usage profile 120 to account for the dissimilarities between the first PE device 100 and the second PE device 100′.

In one embodiment, the power utility 118 can cause the communication mechanism 112 to upload an updated usage pattern 120′ to a shared network 130, which is communicatively accessible to the PE device 100 and to at least one second PE device 100′ to which the updated usage pattern 120′ associated with the user profile 122 can be downloaded. The second PE device 100′ can then in turn download the user profile 122 with the updated usage pattern 120′ from the shared network 130. The second PE device 100′ can apply the updated usage pattern 120′ from the user profile 122 in determining when to generate the user alert 142. The power utility 118 of the second PE device 100′ can further update the updated usage pattern 120′ with new usage information occurring on the second PE device 100′. The shared network 130 can be a point-to-point communication connection between PE device 100 and the second PE device 100′. Alternatively or in addition, the shared network 130 can be over a local or wide area network.

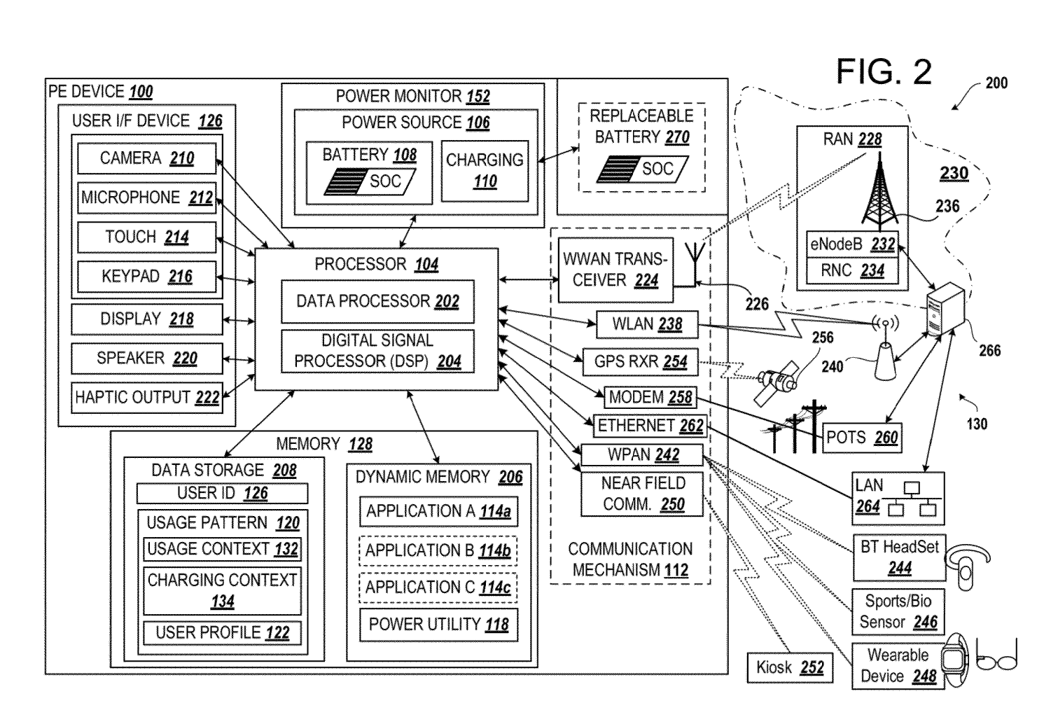

FIG. 2 shows the specific component makeup of an example PE device 100 that is a wireless communication device and/or which supports wireless communication functionality. PE device 100 is depicted as including components presented in FIG. 1 and described above, as well as other components relevant to support the wireless communication functions of PE device 100. Most of the components shown in FIG. 2 that have already been presented in FIG. 1 are not described within the FIG. 2 description. PE device 100 can include an integrated circuit (IC) processor 104, which connects via a plurality of bus interconnects (illustrated by the bi-directional arrows) to a plurality of functional components of PE device 100. The PE device 100 can be one of a host of different types of portable devices, including but not limited to, a mobile cellular phone or smart-phone, a laptop, a net-book, an ultra-book, a networked sports/exercise watch, and/or a tablet computing device. These various devices all provide and/or include the necessary hardware and software to support the various wireless or wired communication functions as part of a communication system 200.

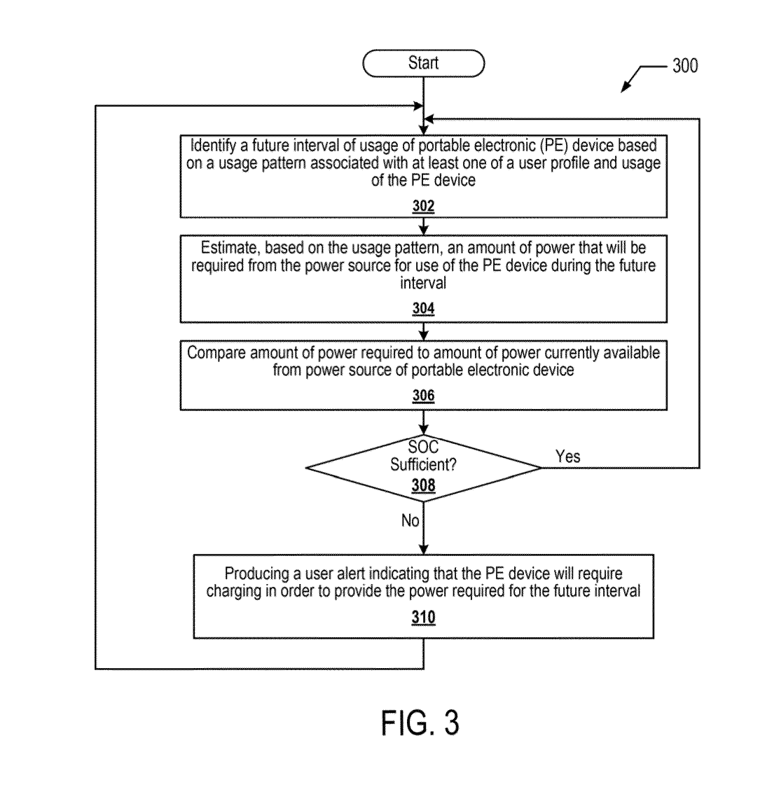

Processor 104 can include one or more programmable microprocessors, such as a data processor 202 and a digital signal processor (DSP) 204, which both may be integrated into a single processing device, in some embodiments. The IC processor 104 controls the communication, user interface, and other functions and/or operations of PE device 100. These functions and/or operations thus include, but are not limited to, application data processing and signal processing. Connected to processor 104 is memory 128, which can include volatile or dynamic memory 206, and/or non-volatile memory, depicted as a data storage device 208. The data storage device 208 that is also coupled to IC processor 104 can be any type of available storage device that is integral, attachable or insertable, and capable of storing one or more application software and data. It is further appreciated that in one or more alternate embodiments, the data storage device 208 can actually be remote storage and not an integral part of the PE device 100 itself. The specific usage and/or functionality associated with these components are described in greater detail in the following descriptions. The associated functionality and/or usage of software modules stored in memory 128 and executed by IC processor 104 will be described in greater detail within the descriptions which follow. In particular, the functionality associated with power utility 118 is described in greater detail with the description of FIGS. 3-8.

In one embodiment, PE device 100 also includes user interface device 140 having one or more input devices, such as camera 210, microphone 212, touch screen and/or touch pad 214, and keypad 216. The touch screen and/or touch pad 214 can function as a fingerprint sensor. Alternatively the user interface device 140 can have a discrete fingerprint sensor. The user interface device 140 can also have one or more output devices, such as display 218, speaker 220, and haptic output device 222.

PE device 100 includes communication mechanism 112, which can support one or more modes of communication in order to transmit usage pattern 120 and to support other functions of the PE device 100. To support wireless communication, communication mechanism 112 of PE device 100 can include one or more communication components, including wireless wide area network (WWAN) transceiver 224 with connected antenna 226 to communicate with a radio access network (RAN) 228 of a cellular network 230. The RAN 228 is generally represented as including a base station, depicted as an evolved base node (“eNodeB”) 232 controlled by a radio network controller (RNC) 234 that transceives signals over a base station antenna 236. For clarity, one connected antenna 226 of the PE device 100 is depicted. However, the PE device 100 may contain more than one antenna, each antenna having one or more selected bandwidths of operation to support different modes of communication or for simultaneous communication in different communication technologies.

Alternatively, or in addition to a WWAN transceiver 224, PE device 100 can include a wireless local access network (WLAN) module 238 to communicate with wireless devices and networks, depicted as a wireless access point 240. Alternatively or in addition, communication mechanism 112 of PE device 100 can include a wireless personal access network (WPAN) transceiver 242 for communication with WPAN devices, depicted as a Bluetooth® headset 244, a sports/biometric/physiological sensor 246, and a wearable device 248 (e.g., multi-function watch, heads up display, etc.). WPAN 242 can include technologies such as Infrared Data Association (IrDA) standard, Wireless Universal Serial Bus (USB), Bluetooth®, Z-Wave, ZigBee, Body Area Network, and ANT+. Alternatively or in addition, communication mechanism 112 of PE device 100 can include a near field communication (NFC) transceiver module 250, such as can be utilized for exchanging files with another user device or a payment kiosk 252. One or more of these WPAN devices can provide contextual data such as by relaying ambient conditions sensed by another device.

A global positioning system (GPS) receiver (RXR) 254 of the communication mechanism 112 can receive signals from GPS satellite(s) 256 in order to provide location as contextual data. Alternatively or in addition to GPS 256, the communication mechanism 112 can provide a location service by triangulating from one or more RANs 228. Alternatively or in addition, location service can be provided by “sniffing” of small coverage area cells such as one or more wireless access points, femtocells, relays, etc. As further illustrated, communication mechanism 112 of PE device 100 can also include components for wired communication, such as modem 258 for communicating over a plain old telephone system (POTS) 260 and Ethernet module 262 for connecting to a local access network (LAN) 264.

Certain functions described herein can be performed remote from the PE device 100 over the shared network 130, further depicted as including a network server 266. In the illustrative depiction, the network server 266 is connected to the cellular network 230, wireless access point 240, POTS 260, and LAN 264.

For clarity, the power source 106 is depicted as having an integral battery 108 that may be rechargeable. Alternatively or in addition, one or more replaceable batteries 270 can be attached or asserted. Battery 108 and replaceable battery 270 can also represent power storage technologies to include supercapacitors and ultracapacitors, and fuel cells.

FIG. 3 is a flow chart that illustrates a method 300 for generating contextual power alerts related to a power source of a PE device, such as PE device 100. According to one or more embodiments, method 300 further illustrates a real-time estimate of battery charge and discharge duration based on a detected usage pattern. In addition, method 300 intelligently recommends to a user when to charge the PE device based on context information. The method 300 begins at start block and proceeds to block 302 which provides the power utility identifying a future interval of usage of the PE device based on a usage pattern associated with at least one of a user profile and usage of the PE device. The power utility estimates in block 304, based on the usage pattern, an amount of charge that is necessary for the power source to power the use of the PE device through the future interval. The power utility compares the amount of charge required for use of the PE device through the future interval to an amount of charge currently available from the power source (block 306). In decision block 308 a determination is made as to whether the amount of charge currently available, depicted as SOC, is sufficient for the power required for use of the PE device through the future interval. In response to determining in decision block 308 that the amount of charge required for use of the PE device through the future interval is greater than an amount of charge currently available from the power source, then in block 310 the power utility produces a user alert. The user alert indicates that the PE device will require charging in order to provide the amount of charge required to power the PE device through the future interval. The method 300 returns to block 302 to continue identifying subsequent future intervals. Also, in response to determining in block 308 that the amount of charge required for use of the PE device through the future interval is not greater than an amount of charge currently available from the power source, then the method 300 returns to block 302 to continue identifying subsequent future intervals.

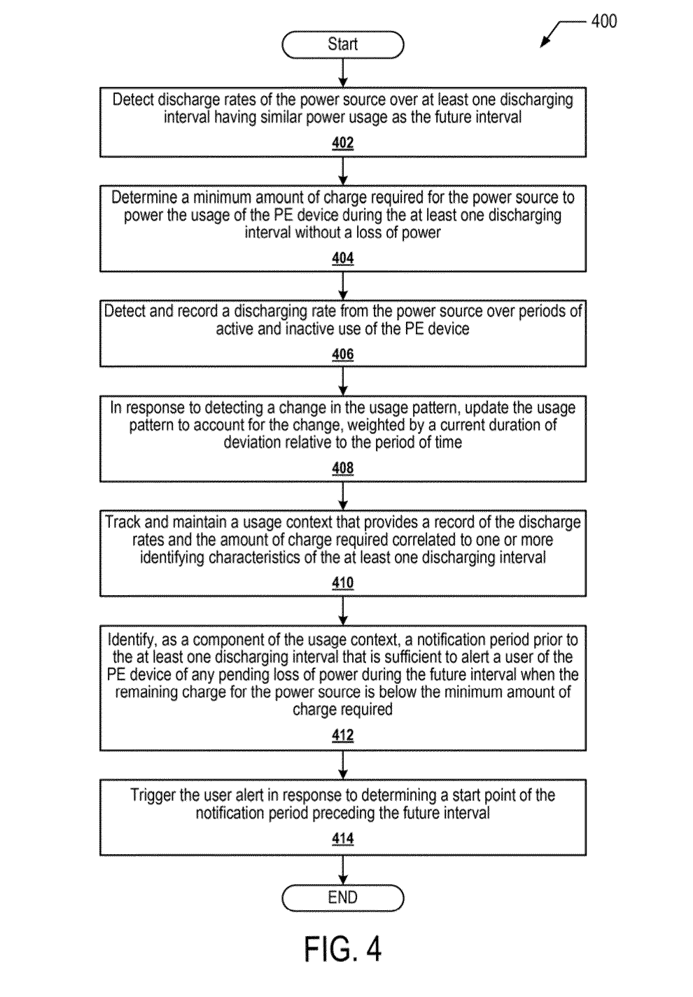

FIG. 4 is a flow chart that illustrates another example method 400 for detecting rates of discharging and for updating usage pattern based upon time-based and location-based usage context. In particular, method 400 is used for a PE device having a power source that holds an amount of charge ranging from a full charge to no charge. The amount of charge is depleted at varying rates based on a level of device usage. According to the illustrative embodiment, method 400 begins at start block and proceeds to block 402 which provides that the power utility detects discharging rates of the power source over at least one discharging interval, which has a discernible periodic power usage pattern. In the described embodiments, the at least one discharging interval becomes an interval that is identified as requiring similar power usage as a future interval of device usage. In block 404, the power utility determines a minimum amount of charge required for the power source to power the usage of the PE device during the at least one discharging interval without the PE device experiencing a loss of power. The power utility detects and records a discharging rate from the power source over periods of active and inactive use of the PE device (block 406). In block 408, in response to detecting a change in the usage pattern, the power utility updates the stored usage pattern to account for the detected change. In particular, the stored usage pattern can be updated as weighted by a current duration of deviation relative to the period of time. In block 410, the power utility tracks and maintains a usage context that provides a record of the discharging rates and the amount of charge required, correlated to one or more identifying characteristics (such as time of day, GPS or other location of the device, etc.) of the at least one discharging interval. In block 412, the power utility identifies a notification period prior to the at least one discharging interval that is sufficient to: (a) alert a user of the PE device of a potential loss of power through the future interval based on a remaining charge for the power source being below the minimum amount of charge required; and (b) allow the user to take corrective action before the future interval. Using the stored usage patterns and other data such as a current amount of battery charge available, the notification period established for that amount of remaining charge, and an amount of charge actually required, the power utility triggers issuance of the user alert in response to determining a start point of the notification period preceding the future interval (block 414). Then method 400 ends at the end block.

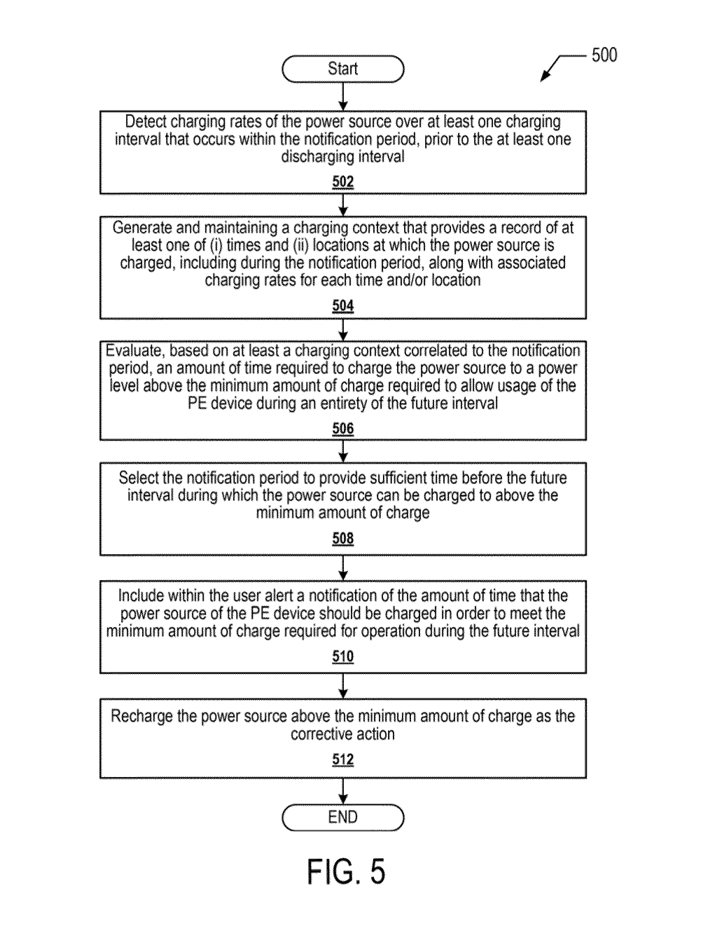

FIG. 5 illustrates a flow chart of an additional example method for detecting rates of charging and for notifying a user as to an amount of time required to charge the PE device for a future usage interval, according to at least one embodiment. Method 500 thus pertains to PE devices having a power source that is rechargeable. According to one or more embodiments, method 500 begins at start block and proceeds to block 502 which provides that the power utility detects charging rates of the power source over at least one charging interval that occurs within the notification period, prior to the at least one discharging future interval. The power utility in block 504 generates and maintains a charging context that provides a record of at least one of (i) times and (ii) locations at which the power source is charged, including during the notification period, along with associated charging rates for each time and/or location. In block 506, the power utility evaluates, based on at least a charging context correlated to the notification period, an amount of time required to charge the power source to a power level above the minimum amount of charge required to allow usage of the PE device during an entirety of the future interval. In block 508, the power utility selects the notification period to provide sufficient time before the future interval during which the power source can be charged to a charge level above the minimum amount of charge. In block 510, the power utility includes within the user alert a notification of the amount of time that the power source of the PE device should be charged in order to meet the minimum amount of charge required for operation through the future interval. The power source of the PE device is then recharged by the user above the minimum amount of charge as the corrective action (block 512). Then the method 500 ends at the end block.

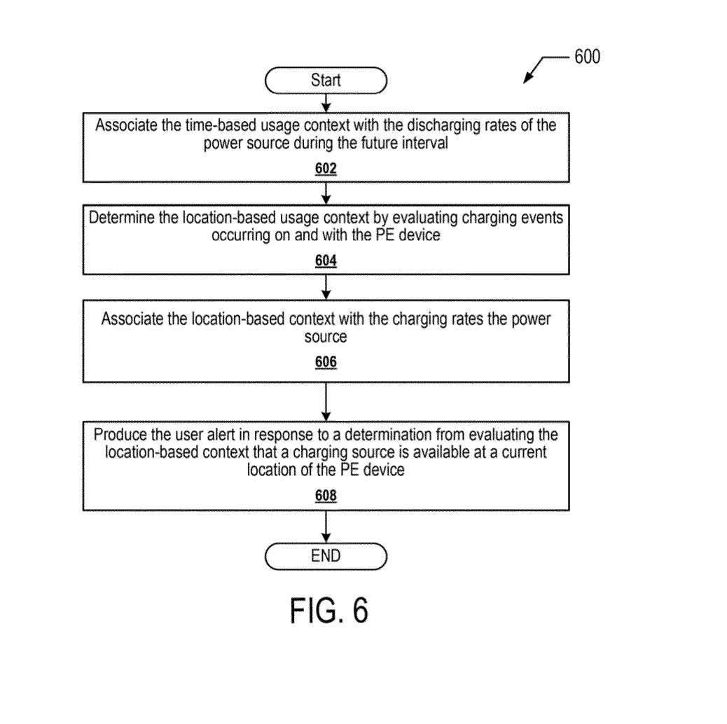

FIG. 6 is a flow chart that illustrates a further example method 600 for determining that charging is available based upon a current context and previously evaluated charging events. According to at least one embodiment, the method 600 provides for the usage context being at least one of a time-based usage context associated with the discharging rates and a location-based usage context associated with charging rates of the power source. According to one or more embodiments, method 600 begins at start block and proceeds to block 602 that provides for the power utility associating the time-based usage context with the discharging rates of the power source through the future interval. The location-based usage context is determined from evaluating charging events occurring on and with the PE device (block 608). In block 606, the power utility associates the location-based usage context with the charging rates of the power source. The power utility in block 608 produces the user alert via a user interface device in response to a determination from evaluating the location-based usage context that a charging source is available at a current location of the PE device. Then the method 600 ends at the end block.

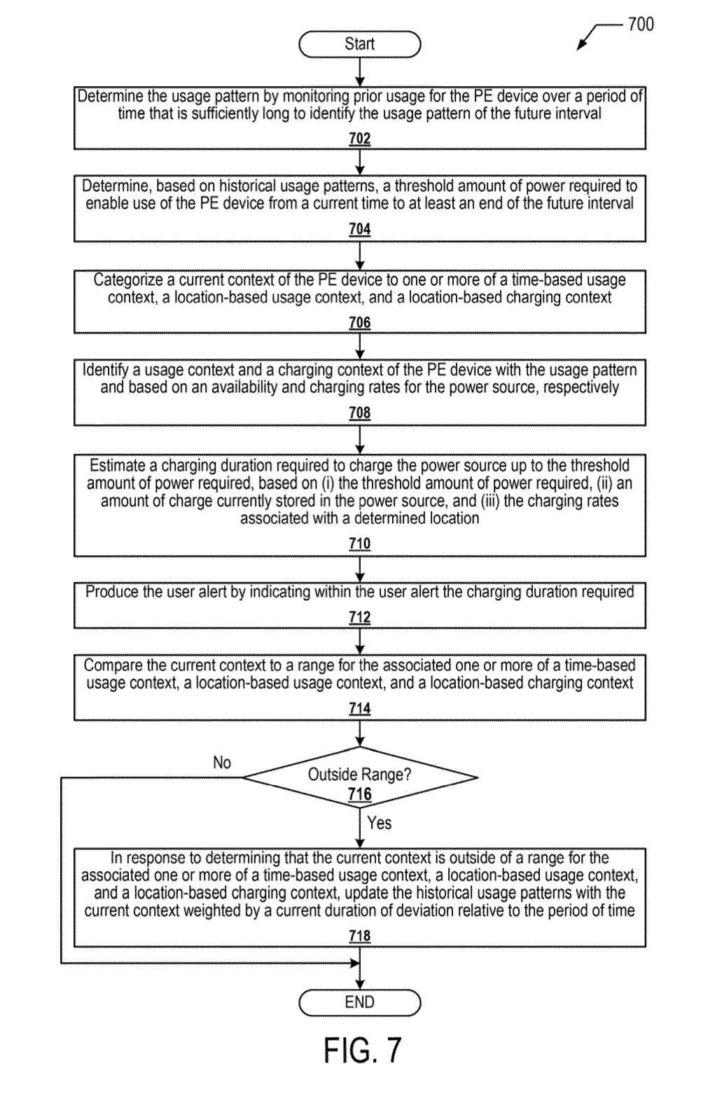

FIG. 7 is a flow chart that illustrates yet another example method 700 for categorizing a current context and for updating a historical usage pattern of the PE device. According to one or more embodiments, method 700 begins at start block and proceeds to block 702 which provides that the power utility determines the usage pattern by monitoring prior usage for the PE device over a period of time that is sufficiently long to identify the usage pattern of the future interval. In block 704, the power utility determines, based on historical usage patterns, a threshold amount of charge required to enable use of the PE device from a current time to at least an end of the future interval. The power utility in block 706 categorizes a current context of the PE device to one or more of a time-based usage context, a location-based usage context, and a location-based charging context. In block 708 the power utility identifies a usage context and a charging context of the PE device with the usage pattern and based on an availability and charging rates for the power source, respectively.

According to at least one embodiment, the power utility estimates a charging duration required to charge the power source up to the threshold amount of charge required, based on (i) the threshold amount of charge required, (ii) an amount of charge currently stored in the power source, and (iii) the charging rates associated with a determined location (block 710). The power utility in block 712 produces the user alert via the user interface that indicates the charging duration required. In block 714, the power utility compares the current context to a range for the associated one or more of a time-based usage context, a location-based usage context, and a location-based charging context. For example, the range can be defined as a percentage threshold above and below an average value. Updating when outside of the range can reduce power consumption and air link resources. Alternatively, the usage pattern is routinely updated as a weighted rolling average as categorized according to context, even if the current value is within the range.

The power utility in decision block 716 determines whether the current context is outside of a range for the associated one or more of a time-based usage context, a location-based usage context, and a location-based charging context. In response to determining that the current context is not outside of a range for the associated one or more of a time-based usage context, a location-based usage context, and a location-based charging context in decision block 716, the method 700 ends at the end block. In block 718, in response to determining that the current context is outside of a range for the associated one or more of a time-based usage context, a location-based usage context, and a location-based charging context in block 716, the PE device updates the historical usage patterns with the current context weighted by a current duration of deviation relative to the period of time over which the stored context was compiled. For example, the changes can be detected by a rolling average in order to appropriately minimize minor deviations from a usage pattern. Then the method 700 ends at the end block.

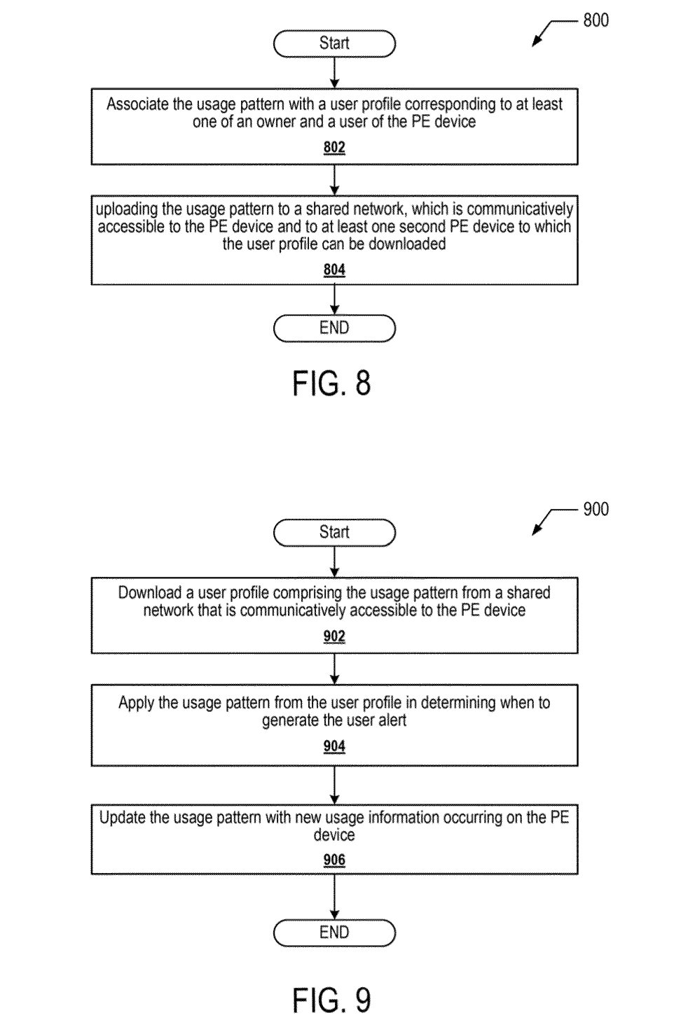

FIG. 8 is a flow chart that illustrates yet a further example method 800 for sharing a user profile between PE devices associated with one user. According to one or more embodiments, method 800 begins at start block and proceeds to block 802 that provides for the power utility associating the usage pattern with a user profile corresponding to at least one of an owner and a user of the PE device. In block 804 the PE devices uploads the usage pattern to a shared network, which is communicatively accessible to the PE device and to at least one second PE device to which the user profile can be downloaded. Then the method 800 ends at the end block.

FIG. 9 is a flow chart that illustrates another example method 900 for sharing the user profile between PE devices associated with one user. In one or more embodiments, where the PE device is a new device being configured for contextual power notification and/or an existing device being configured for a particular user profile that is accessible from the shared network or from the second device, the PE device downloads the user profile including the usage pattern from the shared network that is communicatively accessible to the PE device (block 902). In block 904 the power utility applies the usage pattern from the user profile in determining when to generate the user alert. The PE device in block 906 updates the usage pattern with new usage information occurring on the PE device. Then the method 900 ends at the end block.

In the flow charts of FIGS. 3-8 presented herein, certain steps of the methods can be combined, performed simultaneously or in a different order, or perhaps omitted, without deviating from the spirit and scope of the described innovation. While the method steps are described and illustrated in a particular sequence, use of a specific sequence of steps is not meant to imply any limitations on the innovation. Changes may be made with regards to the sequence of steps without departing from the spirit or scope of the present innovation. Use of a particular sequence is therefore, not to be taken in a limiting sense, and the scope of the present innovation is defined only by the appended claims.

As will be appreciated by one skilled in the art, embodiments of the present innovation may be embodied as a system, device, and/or method. Accordingly, embodiments of the present innovation may take the form of an entirely hardware embodiment or an embodiment combining software and hardware embodiments that may all generally be referred to herein as a “circuit,” “module” or “system.”

Aspects of the present innovation are described below with reference to flowchart illustrations and/or block diagrams of methods, apparatus (systems) and computer program products according to embodiments of the innovation. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

While the innovation has been described with reference to exemplary embodiments, it will be understood by those skilled in the art that various changes may be made and equivalents may be substituted for elements thereof without departing from the scope of the innovation. In addition, many modifications may be made to adapt a particular system, device or component thereof to the teachings of the innovation without departing from the essential scope thereof. Therefore, it is intended that the innovation not be limited to the particular embodiments disclosed for carrying out this innovation, but that the innovation will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the innovation. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof

The corresponding structures, materials, acts, and equivalents of all means or step plus function elements in the claims below are intended to include any structure, material, or act for performing the function in combination with other claimed elements as specifically claimed. The description of the present innovation has been presented for purposes of illustration and description, but is not intended to be exhaustive or limited to the innovation in the form disclosed. Many modifications and variations will be apparent to those of ordinary skill in the art without departing from the scope and spirit of the innovation. The embodiment was chosen and described in order to best explain the principles of the innovation and the practical application, and to enable others of ordinary skill in the art to understand the innovation for various embodiments with various modifications as are suited to the particular use contemplated.

What is claimed is:

1. A method for generating contextual power alerts related to a power source of a portable electronic (PE) device, the method comprising:
identifying a future interval of usage of the PE device based on a usage pattern associated with at least one of a user profile and usage of the PE device;
estimating, based on the usage pattern, an amount of charge that is necessary for the power source to power the use of the PE device through the future interval; and
in response to determining that the amount of charge required for use of the PE device through the future interval is greater than an amount of charge currently available from the power source, producing a user alert indicating that the PE device will require charging in order to provide the amount of charge required to power the PE device through the future interval.

2. The method of claim 1, wherein:
the power source holds an amount of charge ranging from a full charge to no charge, and the amount of charge is depleted at varying rates based on a level of device usage; and
the method further comprises:
detecting discharging rates of the power source over at least one discharging interval having similar power usage as the future interval;
determining a minimum amount of charge required for the power source to power the usage of the PE device during the at least one discharging interval without a loss of power;
tracking and maintaining a usage context that provides a record of the discharging rates and the amount of charge required correlated to one or more identifying characteristics of the at least one discharging interval;
identifying a notification period prior to the at least one discharging interval that is sufficient to (a) alert a user of the PE device of a potential loss of power through the future interval based on a remaining charge for the power source being below the minimum amount of charge required and (b) allow the user to take corrective action before the future interval; and
triggering the user alert in response to determining a start point of the notification period preceding the future interval.

3. The method of claim 2, wherein:
the power source is a rechargeable power source and the corrective action involves recharging the power source above the minimum amount of charge;
the notification period is selected to provide sufficient time before the future interval during which the power source can be charged to above the minimum amount of charge; and
the method further comprises:
detecting charging rates of the power source over at least one charging interval that occurs within the notification period, prior to the at least one discharging interval;
generating and maintaining a charging context that provides a record of at least one of (i) times and (ii) locations at which the power source is charged, including during the notification period, along with associated charging rates for each time and/or location;
evaluating, based on at least a charging context correlated to the notification period, an amount of time required to charge the power source to a power level above the minimum amount of charge required to allow usage of the PE device during an entirety of the future interval; and
including within the user alert a notification of the amount of time that the power source of the PE device should be charged in order to meet the minimum amount of charge required for operation through the future interval.

4. The method of claim 3, wherein:
the usage context comprises at least one of a time-based usage context associated with the discharging rates and a location-based usage context associated with charging rates of the power source; and
the method further comprises:
associating the time-based usage context with the discharging rates of the power source through the future interval:
associating the location-based usage context with the charging rates the power source, wherein the location-based usage context is determined from evaluating charging events occurring on and with the PE device; and
producing the user alert in response to a determination from evaluating the location-based usage context that a charging source is available at a current location of the PE device.

5. The method of claim 3, further comprising:
updating the usage pattern with the detected charging rates and discharging rates of the power source; and
recording the updated usage pattern on the PE device for a subsequent determination of power required during a future interval.

6. The method of claim 1, further comprising:
determining, based on historical usage patterns, a threshold amount of charge required to enable use of the PE device from a current time to at least an end of the future interval;
identifying a usage context of the PE device based upon the usage pattern;
identifying a charging context of the PE device based on an availability and charging rates for the power source as indicated in the usage pattern; and
estimating a charging duration required to charge the power source up to the threshold amount of charge required, based on (i) the threshold amount of charge required, (ii) an amount of charge currently stored in the power source, and (iii) the charging rates associated with a determined location;
wherein producing the user alert comprises indicating within the user alert the charging duration required.

7. The method of claim 6, further comprising:
determining the usage pattern by monitoring prior usage for the PE device over a period of time that is sufficiently long to identify the usage pattern of the future interval; and
categorizing a current context of the PE device to one or more of a time-based usage context, a location-based usage context, and a location-based charging context.

8. The method of claim 7, further comprising:
comparing a current context to the historical usage patterns; and
in response to determining that the current context is outside of a range for the associated one or more of a time-based usage context, a location-based usage context, and a location-based charging context, updating the historical usage patterns with the current context weighted by a current duration of deviation relative to the period of time.

9. The method of claim 1, further comprising:
associating the usage pattern with a user profile corresponding to at least one of an owner and a user of the PE device; and
uploading the usage pattern to a shared network, which is communicatively accessible to the PE device and to at least one second PE device to which the user profile can be downloaded.

10. The method of claim 1, further comprising:
detecting and recording a discharging rate from the power source over periods of active and inactive use of the PE device; and
in response to detecting a change in the usage pattern, updating the usage pattern to account for the change.

11. The method of claim 1, further comprising:
downloading a user profile comprising the usage pattern from a shared network that is communicatively accessible to the PE device;
applying the usage pattern from the user profile in determining when to generate the user alert; and
updating the usage pattern with new usage information occurring on the PE device.

12. A portable electronic (PE) device, comprising:
a power source;
at least one processor that is powered by the power source;
one or more applications selectively executed by the at least one processor;
a user interface device that is communicatively coupled to the at least one processor;
a power utility that executes on the at least one processor and configures the PE device to:
identify a future interval of usage of the PE device based on a usage pattern associated with at least one of a user profile and usage of the PE device;
estimate, based on the usage pattern, an amount of charge that is necessary for the power source to power the use of the PE device through the future interval; and
in response to determining that the amount of charge required for use of the PE device through the future interval is greater than an amount of charge currently available from the power source, produce a user alert indicating that the PE device will require charging in order to provide the amount of charge required to power the PE device through the future interval.

13. The PE device of claim 12, wherein:
the power source holds an amount of charge ranging from a full charge to no charge, and the amount of charge is depleted at varying rates based on a level of device usage;
and wherein the power utility further configures the PE device to:
detect discharging rates of the power source over at least one discharging interval having similar power usage as the future interval;
determine a minimum amount of charge required for the power source to power the usage of the PE device during the at least one discharging interval without a loss of power;
track and maintain a usage context that provides a record of the discharging rates and the amount of charge required correlated to one or more identifying characteristics of the at least one discharging interval;
identify a notification period prior to the at least one discharging interval that is sufficient to (a) alert a user of the PE device of a potential loss of power through the future interval based on a remaining charge for the power source being below the minimum amount of charge required and (b) allow the user to take corrective action before the future interval; and
trigger the user alert in response to determining a start point of the notification period preceding the future interval.

14. The PE device of claim 13, wherein:
the power source is a rechargeable power source and the corrective action involves recharging the power source above the minimum amount of charge;
the notification period is selected to provide sufficient time before the future interval during which the power source can be charged to above the minimum amount of charge;
and wherein the power utility further configures the PE device to:
detect charging rates of the power source over at least one charging interval that occurs within the notification period, prior to the at least one discharging interval;
generate and maintain a charging context that provides a record of at least one of (i) times and (ii) locations at which the power source is charged, including during the notification period, along with associated charging rates for each time and/or location;
evaluate, based on at least a charging context correlated to the notification period, an amount of time required to charge the power source to a power level above the minimum amount of charge required to allow usage of the PE device during an entirety of the future interval; and
include within the user alert a notification of the amount of time that the power source of the PE device should be charged in order to meet the minimum amount of charge required for operation through the future interval.

15. The PE device of claim 14, wherein:
the usage context comprises at least one of a time-based usage context associated with the discharging rates and a location-based usage context associated with charging rates of the power source; and
the power utility further configures the PE device to:
associate the time-based usage context with the discharging rates of the power source through the future interval:
associate the location-based usage context with the charging rates the power source, wherein the location-based usage context is determined from evaluating charging events occurring on and with the PE device; and
produce the user alert in response to a determination from evaluating the location-based usage context that a charging source is available at a current location of the PE device.

16. The PE device of claim 14, wherein the power utility further configures the PE device to:
update the usage pattern with the detected charging rates and discharging rates of the power source; and
record the updated usage pattern on the PE device for a subsequent determination of power required during a future interval.

17. The PE device of claim 12, wherein the power utility further configures the PE device to:
determine, based on historical usage patterns, a threshold amount of charge required to enable use of the PE device from a current time to at least an end of the future interval;
identify a usage context of the PE device based upon the usage pattern;
identify a charging context of the PE device based on an availability and charging rates for the power source as indicated in the usage pattern; and
estimate a charging duration required to charge the power source up to the threshold amount of charge required, based on (i) the threshold amount of charge required, (ii) an amount of charge currently stored in the power source, and (iii) the charging rates associated with a determined location;
wherein power utility configuring the PE device for producing the user alert includes configuring the PE device to indicate within the user alert the charging duration required.

18. The PE device of claim 17, wherein the power utility further configures the PE device to:
determine the usage pattern by monitoring prior usage for the PE device over a period of time that is sufficiently long to identify the usage pattern of the future interval; and
categorize a current context of the PE device to one or more of a time-based usage context, a location-based usage context, and a location-based charging context.

19. The PE device of claim 18, wherein the power utility further configures the PE device to:
compare a current context to the historical usage patterns; and
in response to determining that the current context is outside of a range for the associated one or more of a time-based usage context, a location-based usage context, and a location-based charging context, update the historical usage patterns with the current context weighted by a current duration of deviation relative to the period of time.

20. The PE device of claim 13, wherein the power utility configuring the PE device to:
associate the usage pattern with a user profile corresponding to at least one of an owner and a user of the PE device; and
upload the usage pattern to a shared network, which is communicatively accessible to the PE device and to at least one second PE device to which the user profile can be downloaded.

21. The PE device of claim 12, wherein the power utility further configures the PE device to:
detect and record a discharging rate from the power source over periods of active and inactive use of the PE device; and
in response to detecting a change in the usage pattern, update the usage pattern to account for the change.

22. The PE device of claim 12, wherein the power utility further configures the PE device to:
download a user profile comprising the usage pattern from a shared network that is communicatively accessible to the PE device;
apply the usage pattern from the user profile in determining when to generate the user alert; and
update the usage pattern with new usage information occurring on the PE device.
